(19) United States
(12) Patent Application Publication
(10) Pub. No.: US 2011/0315078 A1
(43) Pub. Date: Dec. 29, 2011

(54) COATING SYSTEM

(75) Inventors: MING-YANG LIAO, Tu-Cheng (TW); CHIA-YING WU, Tu-Cheng (TW)

(73) Assignee: HON HAI PRECISION INDUSTRY CO., LTD., Tu-Cheng (TW)

(21) Appl. No.: 12/909,860

(22) Filed: Oct. 22, 2010

(30) Foreign Application Priority Data
Jun. 29, 2010 (TW) 99121345

(51) Int. Cl. C23C 16/52; C23C 16/00

(52) U.S. Cl. 118/694; 118/726

(57) ABSTRACT

A coating system includes a housing, a coating umbrella, a lift driver, a target material source, and a control device. The housing includes a ceiling and a floor. The coating umbrella is configured for receiving a number of workpieces and is suspended from the ceiling. The lift driver is positioned on the floor of the housing and includes a cylinder and a supporting board connected to the cylinder. The cylinder capable of raising or lowering the supporting board in the housing. The target material source is supported on the supporting board and includes a crucible for receiving a target material. The control device is received in the housing and is electrically connected to the lift driver to control the movement of the lift driver to maintain the distance between the coating umbrella and the target material unchanged.

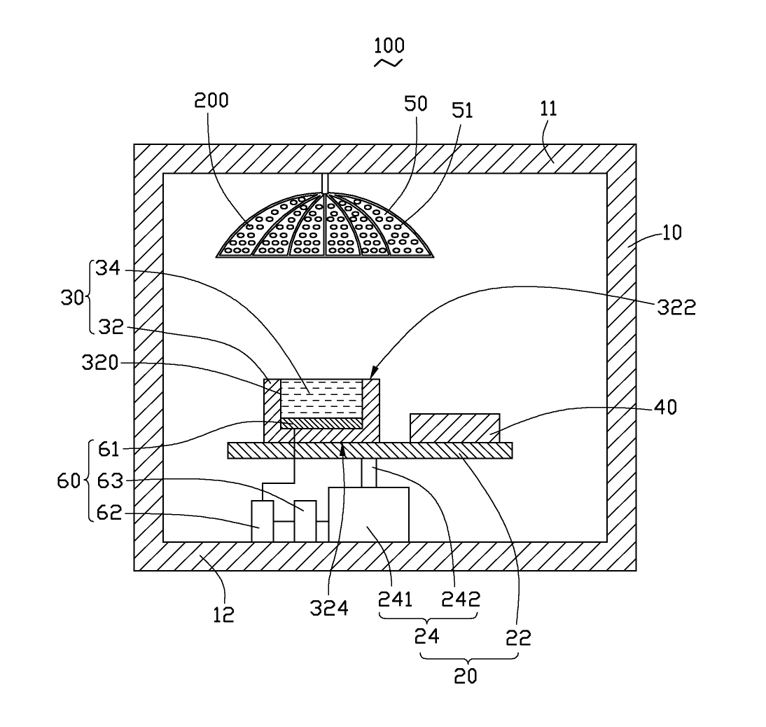

### BACKGROUND

1. Technical Field

The disclosure relates to coating technologies and, particularly, to a coating system.

2. Description of Related Art

Infrared (IR) cut-off filters which reflect or block light of mid-infrared wavelengths while passing visible light are generally equipped in cameras. The IR cut-off filters are manufactured by forming IR cut-off films on workpieces using a coating system. The coating system includes a target material, and a crucible for receiving the target material, a coating umbrella for receiving a number of workpieces, an electron gun for emitting electrons which bombard the target material to vaporize the target material, and a housing for housing the crucible, the target material, the electron gun, and the coating umbrella. The housing includes a ceiling and a floor. The coating umbrella is suspended on the ceiling. The crucible is supported on the floor. However, during the process of coating, as the target material vaporizes, the height of the target material in the crucible reduces and accordingly the distance between the target material and the coating umbrella increases. As a result, electrons of increasingly higher energy levels are required to ensure vaporized target material bombard the workpieces at a substantially constant speed to provide uniform coating.

Therefore, it is desirable to provide a coating system which can overcome the above problems.

### BRIEF DESCRIPTION OF THE DRAWING

Many aspects of the present disclosure can be better understood with reference to the drawing. The components in the drawing are not necessarily drawn to scale, the emphasis instead being placed upon clearly illustrating the principles of the present disclosure.

The drawing is a schematic view of a coating system, according to an exemplary embodiment.

### DETAILED DESCRIPTION

Embodiments of the present disclosure will now be described in detail below and with reference to the drawing.

Referring to the drawing, a coating system 100, according to an exemplary embodiment, includes a housing 10, a lift driver 20, a target material source 30, an electron gun 40, a coating umbrella 50, and a control device 60.

The housing 10 is generally cuboid and includes a ceiling 11 and a floor 12.

The lift driver 20 is positioned on the floor 12 and includes a supporting board 22 and a cylinder 24. The cylinder 24 includes a cylinder body 241 and a piston rod 242 extending outward from the cylinder body 241. An end of the piston rod 242 distant from the cylinder body 241 is connected to the supporting board 22. The cylinder body 241 is positioned on the floor 12. As such, the supporting board 22 can be lifted or lowered by the lift driver 20.

The target material source 30 is received in the housing 10 and supported on the supporting board 22. The target material source 30 includes a crucible 32 and a target material 34. The crucible 32 includes a top surface 322 and a bottom surface 324 opposite to the top surface 322. The crucible 32 defines a receiving groove 320 in the top surface 322 for receiving the target material 34. In the present embodiment, the receiving groove 320 is cuboid in cross section.

The electron gun 40 is also received in the housing 10 and supported on the supporting board 22. The electron gun 40 and the target material source 30 are arranged adjacent to each other. The electron gun 40 is configured for emitting electron beams to bombard the target material 34 to vaporize the target material 34 received in the receiving groove 320.

The coating umbrella 50 is received in the housing 10 and suspended from the ceiling 11. The coating umbrella 50 includes a number of receiving holes 51 facing the top surface 322 of the crucible 32. Each of the receiving holes 51 can receive a workpiece 200. The workpieces 200 can be lenses or metal substrates. In the present embodiment, the workpieces 200 are lenses.

The control device 60 is received in the housing 10 and electrically connected to the lift driver 20 to control movements of the lift driver 20 to maintain the distance between the coating umbrella 50 and the target material 34 unchanged as the target material 34 dwindles.

The control device 60 includes a pressure sensor 61, a calculating unit 62, and a control unit 63. The pressure sensor 61 is positioned on a bottom wall of the receiving grooves 320 and is configured for sensing the pressure applied by the target material 34. Before beginning the coating process, the pressure sensor 61 senses the initial pressure applied by the target material 34. During the coating process, the pressure sensor 61 senses any change in pressure as the mass of the target material 34 in the receiving groove 320 dwindles under bombardment. The calculating unit 62 is electrically connected to the pressure sensor 61. As a result, the calculating unit 62 can calculate the mass m of the target material 34 during the coating process. The calculating unit 62 also stores the area s of the bottom wall of the receiving groove 320 and the density ρ of the target material 34. Thus, the calculating unit 62 is capable of calculating the height of the vaporized target material 34 in the receiving groove 320 according to the formula: h=m/ρsg. The control unit 63 is electrically connected to the calculating unit 62. The control unit 63 controls the lift driver 20 to lift the supporting board 22 to maintain a constant distance between the coating umbrella 50 and the target material 34, based on the height of the vaporized target material 34 in the receiving groove 320.

As compared to typical coating systems, the coating systems 100 is capable of controlling the distance between the coating umbrella 50 and the target material 34. As a result, the costing system 100 need not emit ever higher-energy level electrons to vaporize the target material.

It is understood that the above-described embodiment are intended to illustrate rather than limit the disclosure. Variations may be made to the embodiment without departing from the spirit of the disclosure. Accordingly, it is appropriate that the appended claims be construed broadly and in a manner consistent with the scope of the disclosure.

What is claimed is:

1. A coating system comprising:
a housing comprising a ceiling and a floor;
a coating umbrella for receiving a plurality of workpieces and suspended from the ceiling;
a lift driver positioned on the floor of the housing and comprising a cylinder and a supporting board connected to the cylinder, the cylinder capable of raising or lowering the supporting board in the housing;
a target material source supported on the supporting board and comprising a crucible for receiving a target material; and
a control device received in the housing and electrically connected to the lift driver to control the movement of the lift driver to maintain the distance between the coating umbrella and the target material unchanged as the target material dwindles.

2. The coating system of claim 1, wherein the crucible comprises a top surface facing the coating umbrella, the crucible defines a receiving groove in the top surface for receiving the target material.

3. The coating system of claim 2, wherein the control device comprises a pressure sensor, a calculating unit, and a control unit, the pressure sensor is positioned in a lower surface of the receiving groove and is configured for sensing a pressure applied by the target material, the calculating unit is electrically connected to the pressure sensor to calculate a height of the target material during a coating process, the control unit is configured for controlling the lift driver to maintain the distance between the coating umbrella and the target material unchanged, based on the height calculated by the calculating unit.

4. The coating system of claim 1, wherein the cylinder comprises a cylinder body and a piston rod extending outward from the cylinder body, and an end of the piston rod distant from the cylinder body is connected to the supporting board.

5. The coating system of claim 1, wherein the workpieces are lenses.

6. The coating system of claim 2, wherein the receiving groove is cuboid in cross section.

7. A coating system comprising:
a housing comprising a ceiling and a floor;
a coating umbrella for receiving a plurality of workpieces and suspended from the ceiling;
a lift driver positioned on the floor of the housing and comprising a cylinder and a supporting board connected to the cylinder, the cylinder capable of raising or lowering the supporting board in the housing;
a target material source supported on the supporting board and comprising a crucible for receiving a target material;
an electron gun received in the housing and supported on the supporting board, the electron gun configured to vaporize the target material received in the crucible; and
a control device received in the housing and electrically connected to the lift driver to control the movement of the lift driver to maintain the distance between the coating umbrella and the target material unchanged.

8. The coating system of claim 7, wherein the crucible comprises a top surface facing the coating umbrella, the crucible defines a receiving groove in the top surface for receiving the target material.

9. The coating system of claim 8, wherein the control device comprises a pressure sensor, a calculating unit, and a control unit, the pressure sensor is positioned in a lower surface of the receiving groove and is configured for sensing a pressure applied by the target material, the calculating unit is electrically connected to the pressure sensor to calculate a height of the target material during a coating process, the control unit is configured for controlling the lift driver to maintain the distance between the coating umbrella and the target material unchanged, based on the height calculated by the calculating unit.

10. The coating system of claim 7, wherein the cylinder comprises a cylinder body and a piston rod extending from the cylinder body, an end of the piston rod distant from the cylinder body is connected to the supporting board.

11. The coating system of claim 7, wherein the workpieces are lenses.

12. The coating system of claim 7, wherein the electron gun and the target material source are arranged adjacent to each other.

13. The coating system of claim 8, wherein the receiving groove is cuboid in cross section.

14. The coating system of claim 7, wherein the electron gun is configured for emitting electron beams to bombard the target material.
